(19) United States
(12) Patent Application Publication
(10) Pub. No.: US 2014/0042501 A1
(43) Pub. Date: Feb. 13, 2014

(54) MOS TRANSISTOR AND PROCESS THEREOF

(71) Applicants: Jei-Ming Chen, Tainan City (TW); Chih-Chien Liu, Taipei City (TW); Yu-Shu Lin, Ping-Tung County (TW); Tzu-Chin Wu, Chiayi County (TW)

(72) Inventors: Jei-Ming Chen, Tainan City (TW); Chih-Chien Liu, Taipei City (TW); Yu-Shu Lin, Ping-Tung County (TW); Tzu-Chin Wu, Chiayi County (TW)

(21) Appl. No.: 13/571,369

(22) Filed: Aug. 10, 2012

(51) Int. Cl. H01L 29/78; H01L 21/336

(52) U.S. Cl. 257/288; 438/301; 257/E29.255; 257/E21.438

(57) ABSTRACT

A MOS transistor includes a gate structure and a spacer. The gate structure is located on a substrate. The spacer is located on the substrate beside the gate structure, and the spacer includes an L-shaped inner spacer and an outer spacer, wherein the outer spacer is located on the L-shaped inner spacer, and the two ends of the L-shaped inner spacer protrude from the outer spacer. Moreover, the present invention also provides a MOS transistor process for forming the MOS transistor.

### BACKGROUND OF THE INVENTION

1. Field of the Invention

The present invention relates generally to a MOS transistor and a process thereof, and more specifically to a MOS transistor and a process thereof that forms a spacer including an L-shaped inner spacer and an outer spacer.

2. Description of the Prior Art

Metal-oxide-semiconductor (MOS) transistors are important components in semiconductor integrated circuits, and the electrical performances of a gate and a source/drain in a MOS transistor play an important role for the efficiency of the MOS transistor. Thus, a metal silicide layer is often formed on the gate or the source/drain, enabling good ohmic contacts for metal formed later on the gate or the source/drain, in order to reduce the sheet resistance of the gate and the source/drain, and enhance the operating velocity of the MOS transistor. After the metal silicide layer is formed on the gate or the source/drain, the spacer beside the gate used to form the source/drain is removed, enabling a stress layer later covered to be closer to a gate channel under the gate, so as to enhance the performances of inducing stresses to the gate channel so that improving the carrier mobility in the gate channel. Then, a contact etch stop layer is formed to entirely cover the gate and the substrate. The contact etch stop layer may contain stresses to force the gate channel, and can be an etch stop layer when forming contact holes. After the spacer is removed and the contact etch stop layer is formed by aforesaid method, an interdielectric layer is formed and contact holes are formed in the interdielectric layer by using the contact etch stop layer as an etch stop layer. Metal is then filled into the contact holes to form contact plugs.

However, as the contact plugs are formed by said processing steps, cavities will be generated between each of the gates after the contact etch stop layer is covered, due to the too small spacing between each of the gates, so that the metal used to form the contact plugs will also be filled into the cavities while filling into the contact holes, leading to the contact plugs to be electrically connected to each other and thereby creating short circuits.

### SUMMARY OF THE INVENTION

The present invention provides a MOS transistor and a process thereof, which forms a spacer on the substrate beside the gate structure, and the spacer includes an L-shaped inner spacer and an outer spacer. Therefore, the aforesaid problem can be solved by changing the covering cross-sectional profile of a later formed contact etch stop layer.

The present invention provides a MOS transistor including a gate structure and a spacer. The gate structure is located on a substrate. The spacer is located on the substrate beside the gate structure, and the spacer includes an L-shaped inner spacer and an outer spacer, wherein the outer spacer is located on the L-shaped inner spacer, and the two ends of the L-shaped inner spacer protrudes from the outer spacer.

The present invention provides a MOS transistor process including the following steps. A gate structure is formed on a substrate. A spacer is formed on the substrate beside the gate structure, and the spacer includes an L-shaped inner spacer and an outer spacer, wherein the outer spacer is located on the L-shaped inner spacer, and the two ends of the L-shaped inner spacer protrude from the outer spacer.

According to the above, the MOS transistor is provided and the process thereof forms a spacer including an L-shaped inner spacer and an outer spacer on the substrate beside the gate structure, wherein the outer spacer is located on the L-shaped inner spacer, and the two ends of the L-shaped inner spacer protrude from the outer spacer. Therefore, a contact etch stop layer covering the spacer has a cross-sectional profile, enabling spacings between each of the gate structures (which may be polysilicon gates or metal gates etc) shrinking and the spacings have an opening narrowing from top to bottom. Thus, cavities can be avoided, and a metal for forming contact plugs can just be filled into the predetermined contact holes without filling the cavities, so contact plugs electrically contacting each other can be prevented and short circuits will not occur.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 schematically depict cross-sectional views of a MOS transistor process according to a first embodiment of the present invention.

FIGS. 9-10 schematically depict cross-sectional views of a MOS transistor process according to a second embodiment of the present invention.

FIG. 11 schematically depicts a cross-sectional view of a MOS transistor process according to a third embodiment of the present invention.

FIG. 12 schematically depicts a cross-sectional view of two MOS transistors according to the first embodiment of the present invention.

### DETAILED DESCRIPTION

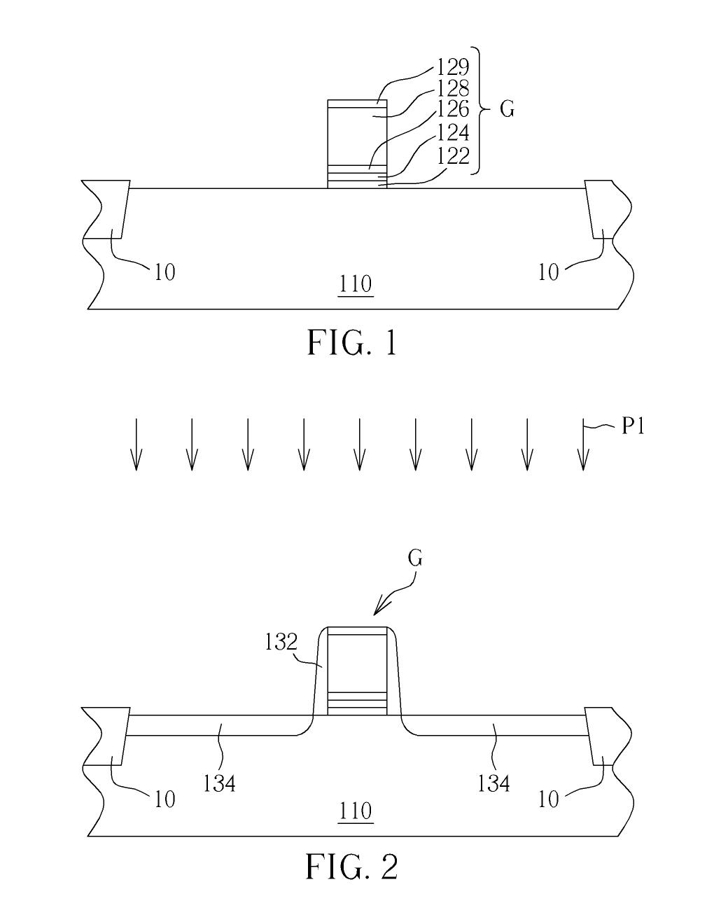

FIGS. 1-8 schematically depict cross-sectional views of a MOS transistor process according to a first embodiment of the present invention. As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. An isolation structure 10 is formed in the substrate 110 to electrically isolate each transistor. The isolation structure 10 may be a shallow trench isolation (STI) structure, which may be formed through a shallow trench isolation process, and the forming method is known in the art, and will not be described herein, but it is not limited thereto.

A buffer layer (not shown), a gate dielectric layer (not shown), a barrier layer (not shown), a sacrificial electrode layer (not shown) and a cap layer (not shown) are sequentially formed from bottom to top and cover the substrate 110. The cap layer (not shown), the sacrificial electrode layer (not shown), the barrier layer (not shown), the gate dielectric layer (not shown) and the buffer layer (not shown) are patterned to form a buffer layer 122, a gate dielectric layer 124, a barrier layer 126, a sacrificial electrode layer 128 and a cap layer 129 on the substrate 110. This means that a sacrificial gate G including the buffer layer 122, the gate dielectric layer 124, the barrier layer 126, the sacrificial electrode layer 128 and the cap layer 129 is now formed.

The buffer layer 122 may be an oxide layer, which may be formed through a chemical oxide process or a thermal oxide process, but it is not limited thereto. The buffer layer 122 is located between the gate dielectric layer 124 and the substrate 110 to buffer the gate dielectric layer 124 and the substrate 110. A gate-last for high-k first process is applied in this embodiment, so that the gate dielectric layer 124 is a gate dielectric layer having a high dielectric constant, which may be the group selected from hafnium oxide (HfO2), hafnium silicon oxide (HfSiO4), hafnium silicon oxynitride (HfSiON), aluminum oxide (Al2O3), lanthanum oxide (La2O3), tantalum oxide (Ta2O5), yttrium oxide (Y2O3), zirconium oxide (ZrO2), strontium titanate oxide (SrTiO3), zirconium silicon oxide (ZrSiO4), hafnium zirconium oxide (HfZrO4), strontium bismuth tantalite (SrBi2Ta2O9, SBT), lead zirconate titanate (PbZrxTi1-xO3, PZT) and barium strontium titanate (BaxSr1-xTiO3, BST), but it is not limited thereto. In another embodiment, as a gate-last for high-k last process is applied, wherein the gate dielectric layer 124 will be removed in later processes and a gate dielectric layer having a high dielectric constant is then formed. Therefore, the material of the gate dielectric layer 124 may be just a sacrificial material suitable for being removed in later processes. The barrier layer 126 is located on the gate dielectric layer 124 to prevent above disposed metals from diffusing downwards to the gate dielectric layer 124 and from polluting the gate dielectric layer 124. The barrier layer 126 may be a single layer structure or a multilayer structure composed of tantalum nitride (TaN) or titanium nitride (TiN) etc. The sacrificial electrode layer 128 may be made of polysilicon, but it is not limited thereto. The cap layer 129 may be a single layer or a multilayer composed of a nitride layer or an oxide layer, etc. used to be a patterned hard mask, but it is not limited thereto.

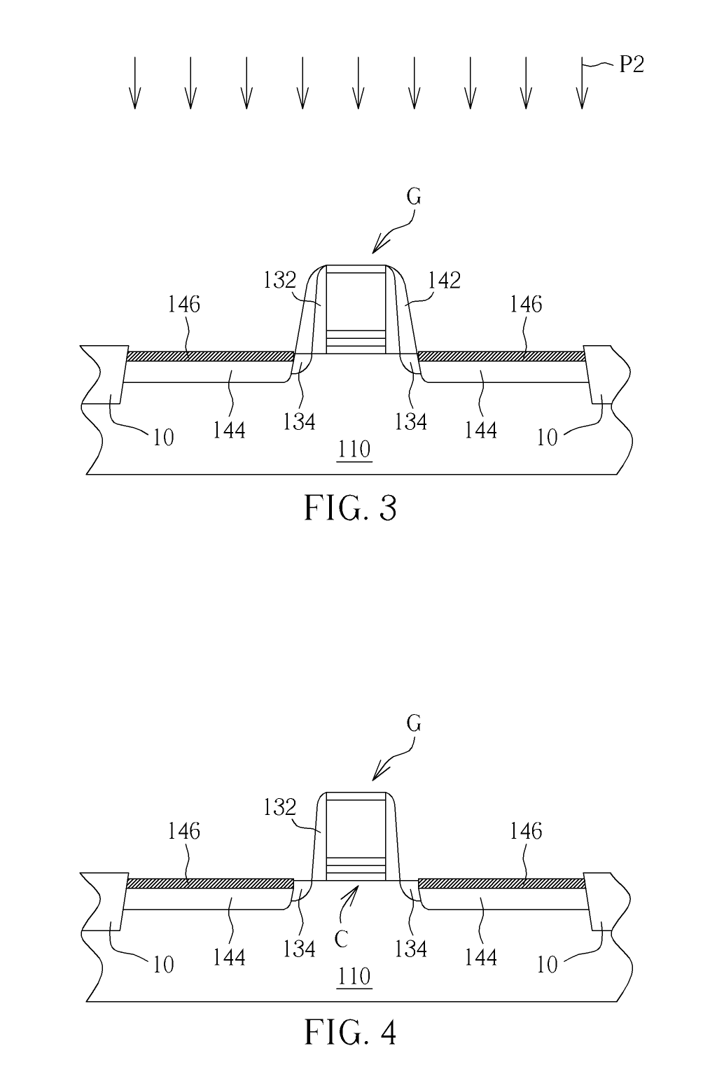

As shown in FIG. 2, a first spacer 132 may be selectively formed on the substrate 110 beside the sacrificial gate G. A lightly doped ion implantation process P1 is performed to automatically align and form a lightly doped source/drain 134 in the substrate 110 beside the first spacer 132. As shown in FIG. 3, a main spacer 142 is formed on the substrate 110 beside the first spacer 132. An ion implantation process P2 is performed to automatically align and form a source/drain 144 in the substrate 110 beside the main spacer 142. A metal silicide (Salicide) process may be selectively performed to form a metal silicide 146 on the source/drain 144. The first spacer 132 or the main spacer 142 may all be a single layer or multilayers composed of silicon nitride or silicon oxide etc. The dopants doped into the source/drain 144 depend upon the transistor types. For example, phosphorus may be doped into the source/drain 144 to form an NMOS transistor; boron may be doped into the source/drain 144 to form a PMOS transistor. The metal silicide 146 may be a silicon/Nicole metal silicide, but it is not limited thereto.

After the source/drain 144 is formed, the main spacer 142 is removed, so that the first spacer 132 is exposed as shown in FIG. 4, enabling spacers or a contact etch stop layer (CESL) having stresses forcing a gate channel C and formed in later processes to be closer to the gate channel C below the sacrificial gate G, in order to increase the stresses forcing the gate channel C provided by the spacers or the contact etch stop layer (CESL). In this embodiment, the main spacer 142 is entirely removed, and the first spacer 132 is exposed. In another embodiment, the main spacer 142 may just be removed partially or the main spacer 142 is entirely removed and the first spacer 132 is partly removed, depending upon the needs.

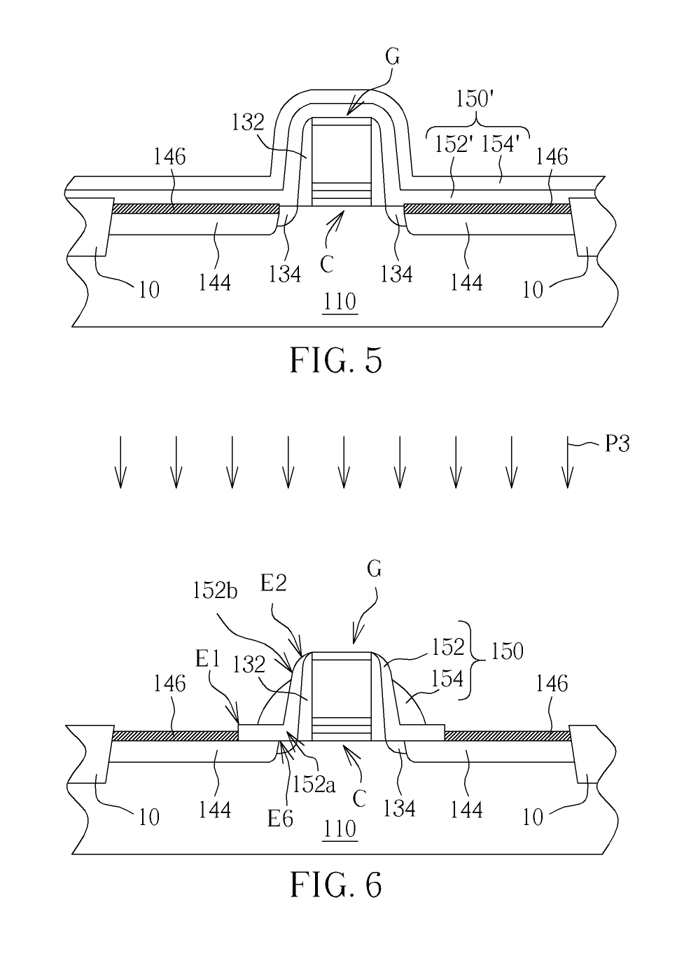

As shown in FIG. 5, a spacer material layer 150′ is formed to entirely cover the sacrificial gate G and the substrate 110. The spacer material layer 150′ may include a stacked structure including an inner spacer material layer 152′ and an outer spacer material layer 154′. In this embodiment, the inner spacer material layer 152′ may be an oxide layer and the outer spacer material layer 154′ may be a nitride layer, but it is not limited thereto. In a preferred embodiment, the inner spacer material layer 152′ and the outer spacer material layer 154′ have different etching rates for an etching process for forming a structure of the present invention so there is a etching selectivity between the inner spacer material layer 152′ and the outer spacer material layer 154′. Furthermore, the outer spacer material layer 154′ is preferred to be a stress layer that induces stresses to the gate channel C.

As shown in FIG. 6, an etching process P3 is performed to etch the spacer material layer 150′ to form a spacer 150 including an L-shaped inner spacer 152 and an outer spacer 154. It is worth noting that, the outer spacer 154 is located on the L-shaped inner spacer 152 in the present invention, and the end E1 of the horizontal part 152a of the L-shaped inner spacer 152 and the end E2 of the vertical part 152b of the L-shaped inner spacer 152 protrude from the outer spacer 154. To form the spacer 150 of the present invention, the etching process P3 may be a single etching process, which may be a dry etching process or a wet etching process having different etching rates to the L-shaped inner spacer 152 and the outer spacer 154. This means that the etching rate to the outer spacer 154 is larger than the etching rate to the L-shaped inner spacer 152. By doing this, the spacer 150 of the present invention, wherein the two ends E1 and E2 of the L-shaped inner spacer 152 protrude from the outer spacer 154, can be formed. The etching process P3 may include two etching processes or a plurality of etching processes. The two etching processes may include two dry etching processes, two wet etching processes, a dry etching process and a wet etching process or etc, and the two etching processes may respectively have different etching selectivities to the L-shaped inner spacer 152 and the outer spacer 154. For instance, a spacer (not shown) including an L-shaped inner spacer and an outer spacer, wherein the two ends of the L-shaped inner spacer are leveled with the outer spacer, is formed through the first etching process having substantially the same etching rate to the L-shaped inner spacer 152 and the outer spacer 154. Thereafter, the second etching process having different etching rates to the L-shaped inner spacer 152 and the outer spacer 154 is performed, wherein the etching rate of the second etching process to the L-shaped inner spacer 152 is different from the etching rate of the second etching process to the outer spacer 154. The spacer 150 of the present invention is now formed, wherein the two ends E1 and E2 of the L-shaped inner spacer 152 protrude from the outer spacer 154. In this embodiment, due to the inner spacer material layer 152′ being an oxide layer, the L-shaped inner spacer 152 is an oxide spacer; the outer spacer material layer 154′ being a nitride layer, the outer spacer 154 is a nitride spacer, but it is not limited thereto. In a preferred embodiment, the outer spacer material layer 154′ is a stress layer and may have had a surface treatment such as doping, ultraviolet emitting or heating performed thereon, so that the outer spacer 154 can be formed as a stress layer, enabling stresses to force a gate channel C. The type of the stress spacer depends upon the electrical type of the formed transistor. For instance, when the transistor is a NMOS transistor, the stress spacer may include a nitride spacer providing tensile stresses; when the transistor is a PMOS transistor, the stress spacer may include a nitride spacer providing compressive stress, but it is not limited thereto.

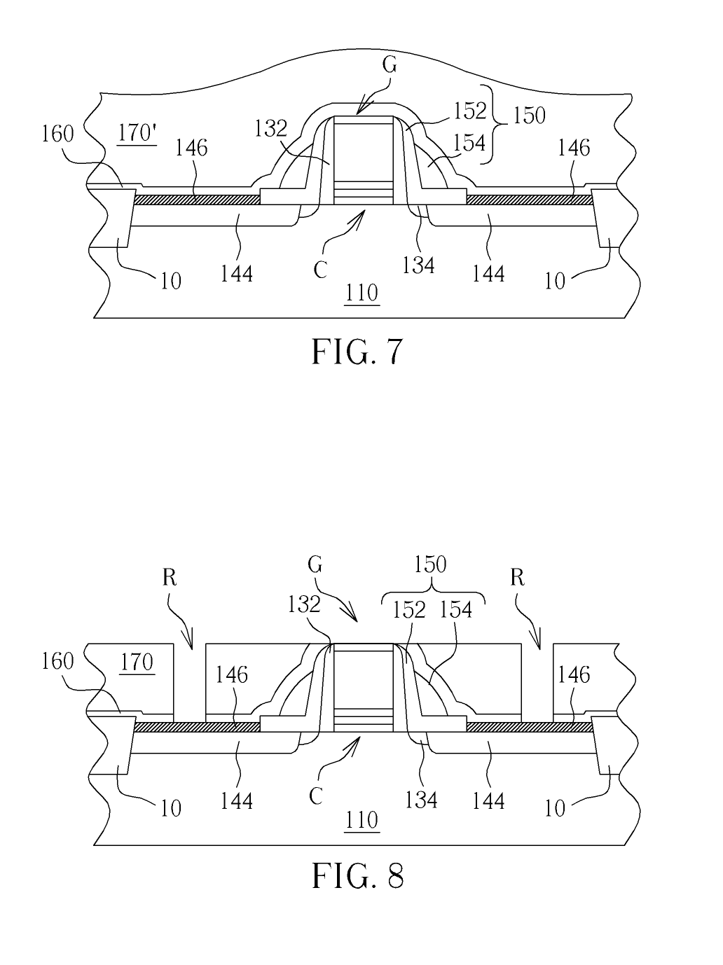

As shown in FIG. 7, a contact etch stop layer 160 may be selectively formed to cover the sacrificial gate G, the spacer 150 and the substrate 110, to serve as an etch stop layer for forming contact holes in an etching process. Furthermore, the contact etch stop layer 160 may also be a stress layer, to induce stresses onto the gate channel C. The type of the stress depends upon the type of the formed transistor. For example, when the transistor is an NMOS transistor, the stress is a tensile stress; when the transistor is a PMOS transistor, the stress is a compressive stress, but it is not limited thereto. In this embodiment, the contact etch stop layer 160 is a contact etch stop layer of a single layer, which may be a nitride layer, and a stress layer having had a surface treatment such as doping, ultraviolet emitting or heating etc performed on it. In another embodiment, the contact etch stop layer 160 is a contact etch stop layer of two layers or multi-layers. For example, the contact etch stop layer 160 may be a contact etch stop layer of two layers composed of a nitride layer stacked on an oxide layer. The nitride layer may be doped to be a stress layer, and the oxide layer may serve as an etch stop layer during etching the nitride layer to prevent underlying structures from being damaged during the etching step.

An interdielectric layer 170′ is formed to cover the contact etch stop layer 160, wherein the interdielectric layer 170′ may be an oxide layer, but it is not limited thereto.

Then, the interdielectric layer 170′ is planarized, so that a planarized interdielectric layer 170 is formed as shown in FIG. 8. For instance, an etching process is performed to form at least a contact hole R in the planarized interdielectric layer 170 and the contact etch stop layer 160, and expose the metal silicide 146. In another embodiment, after at least a contact hole R is formed in the interdielectric layer 170 and the contact etch stop layer 160 and the source/drain is exposed, a metal silicide 146 may be formed on the source/drain 144 by a metal silicide (Salicide) process. Then, metal is filled into the contact holes R and a metal plug (not shown) is therefore formed in each of the contact holes R to electrically connect the source/drain 144 to other semiconductor components. Semiconductor processes may be performed previously, for example, a metal gate replacement process may be performed to replace the sacrificial gate G by a metal gate (not shown).

Above all, in this embodiment, after the source/drain 144 and the metal silicide 146 are formed, the main spacer 142 is removed and the spacer 150 including the L-shaped inner spacer 152 and the outer spacer 154 is formed on the substrate 110 beside the first spacer 132, wherein the outer spacer 154 having properties of inducing stresses is located on the L-shaped inner spacer 152 and the two ends E1 and E2 of the L-shaped inner spacer 152 protrude from the outer spacer 154. By doing this, as shown in FIG. 12, the contact etch stop layer 160 formed outside the spacer 150 has a cross-sectional profile, enabling spacings between each of the sacrificial gate G to be reduced and the spacing having an opening r narrowing from top to bottom (because the end E1 of the lower disposed L-shaped inner spacer 152 protrudes from the upper disposed outer spacer 154). Therefore, cavities can be avoided from being generated, so that the metal for forming the contact plugs (not shown) can just fill the contact holes R without filling the cavities, which will would lead the contact plugs (not shown) to electrically be connected to each other and causing short circuits between each transistors.

As shown in FIGS. 1-8 of the first embodiment, the main spacer 142 is formed on the substrate 110 beside the first spacer 132 to automatically align and form the source/drain 144 in the substrate 110 beside the main spacer 142; the metal silicide 146 is formed on the source/drain 144; the main spacer 142 is removed and then the spacer 150 is formed on the substrate 110 beside the first spacer 132; then, the contact etch stop layer 160 is covered. In another embodiment, after the source/drain 144 is formed, the main spacer 142 is removed, and the spacer 150 is formed on the substrate 110 beside the first spacer 132; the metal silicide 146 is formed on the source/drain 144; and then the contact etch stop layer 160 is covered. In other words, the spacer 150 of the present invention is formed after the source/drain 144 is formed and before/after the metal silicide 146 is formed.

In the first embodiment, the main spacer 142 is removed, and the spacer material layer 150′ is formed and etched to form the spacer 150. In another way, a second and a third embodiment are presented in the following, which forms a main spacer including an L-shaped inner spacer and an outer spacer to automatically align and form a source/drain and then etching the main spacer directly to form a spacer of the present invention.

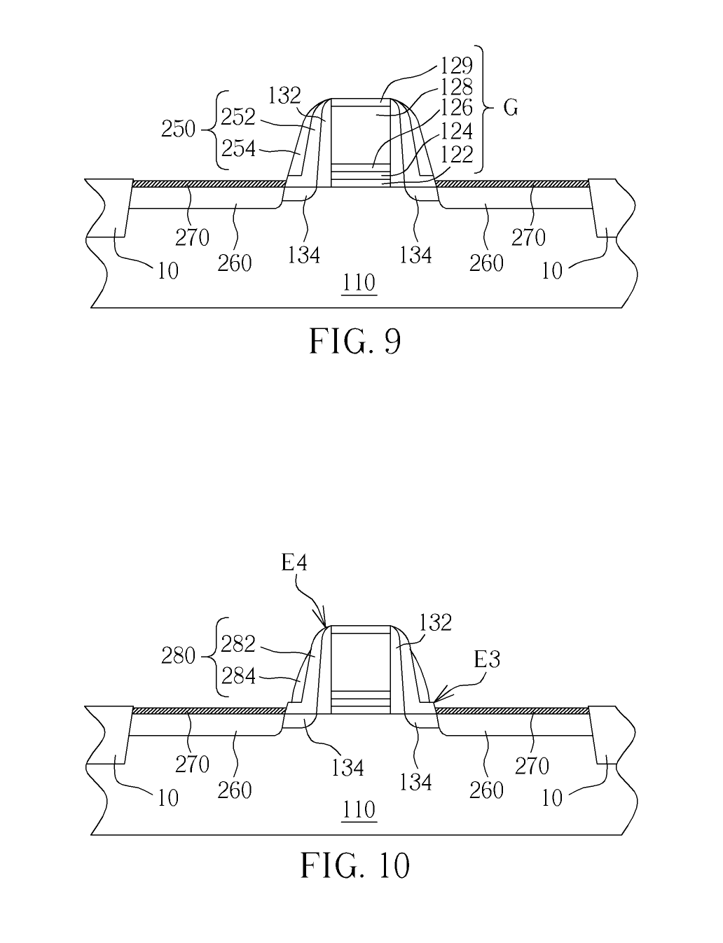

FIGS. 9-10 schematically depict cross-sectional views of a MOS transistor process according to a second embodiment of the present invention. The first steps of the second embodiment are the same as the first steps of the first embodiment (as shown in FIGS. 1-2). This means that the first steps include: the substrate 110 is provided, the sacrificial gate G including the buffer layer 122, the gate dielectric layer 124, the barrier layer 126, the sacrificial electrode layer 128 and the cap layer 129 are formed on the substrate 110; the first spacer 132 is formed on the substrate 110 beside the sacrificial gate G; the lightly doped source/drain 134 is formed in the substrate 110 beside the first spacer 132.

As shown in FIG. 9, a main spacer 250 is formed on the substrate 110 beside the first spacer 132 to automatically align and form a source/drain 260 in the substrate 110 beside the main spacer 250. It is worth noting that the main spacer 250 of this embodiment includes an L-shaped inner spacer 252 and an outer spacer 254. Then, a metal silicide 270 is formed on the source/drain 260.

As shown in FIG. 10, the main spacer 250 is etched to form a spacer 280 including an outer spacer 284 located on an L-shaped inner spacer 282, and the two ends E3 and E4 of the L-shaped inner spacer 282 protrude from the outer spacer 284. Specifically, the method of forming the spacer 280 by the main spacer 250 may include the following steps, but it is not limited thereto. For example, an etching process having different etching rates to the L-shaped inner spacer 282 and the outer spacer 284 is performed wherein the etching rate to the outer spacer 284 is larger than the etching rate to the L-shaped inner spacer 282. Therefore, the spacer 280 including the two ends E1 and E2 of the L-shaped inner spacer 282 protruding from the outer spacer 284 can be formed, and the outer spacer 254 may have a suitable stress, but it is not limited thereto. Thereafter, the process of FIG. 7 and later processes described in the first embodiment can be similarly performed.

In this embodiment, after the source/drain 260 is formed, the metal silicide 270 is formed on the source/drain 260, and then the main spacer 250 is directly etched to form the spacer 280.

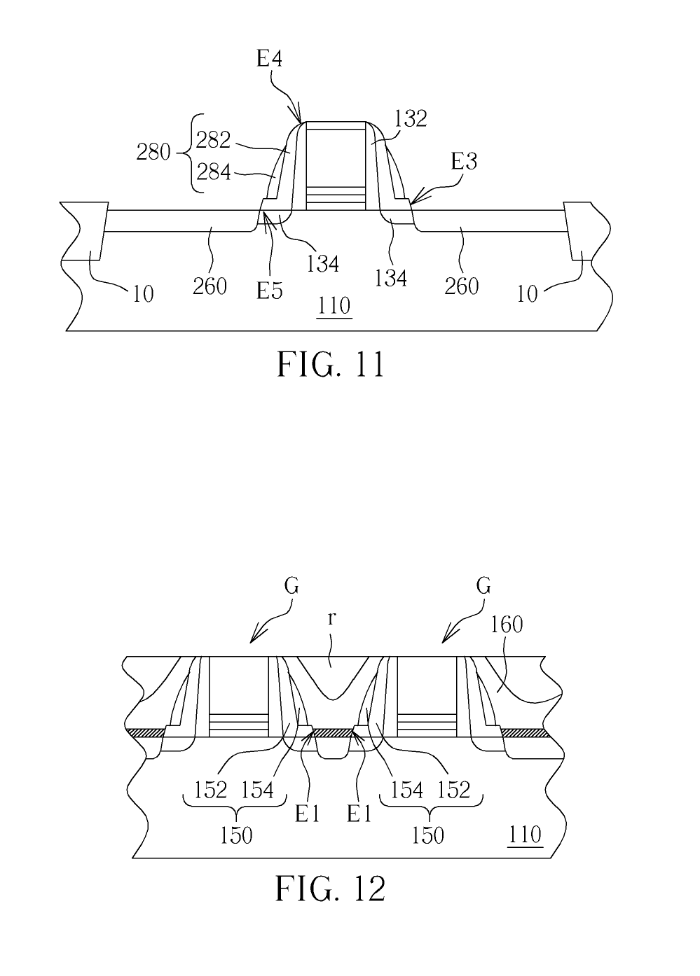

FIG. 11 schematically depicts a cross-sectional view of a MOS transistor process according to a third embodiment of the present invention. As shown in FIG. 11, the differences between the third embodiment and FIGS. 9-10 of the second embodiment are described as following. In this embodiment, a main spacer (not shown) is formed on the substrate 110 beside the first spacer 132 to automatically align and form the source/drain 260 in the substrate 110 beside the main spacer (not shown). Then, the main spacer (not shown) is etched directly to form the spacer 280 including the outer spacer 284 on the L-shaped inner spacer 282, and the two ends E3 and E4 of the L-shaped inner spacer 282 protrude from the outer spacer 284. A metal silicide process is performed to form the metal silicide (not shown) on the source/drain 260.

The structures formed by FIGS. 9-10 of the second embodiment and FIG. 11 of the third embodiment may be different from the structure formed by FIGS. 1-8 of the first embodiment. Since the spacer 280 in the second and the third embodiments are formed by etching the main spacer 250, the edge E5 of the source/drain 260 in the second and the third embodiment is substantially flush with the end E3 of the spacer 280 (as shown in FIG. 11). However, since the spacer 150 of the first embodiment is further formed after the main spacer 142 is removed, the edge E6 of the source/drain 144 may be closer to or farther from the sacrificial gate G than the end E1 of the spacer 150. The MOS transistor processes of the present invention can be selected upon the practical needs.

To summarize, a MOS transistor is formed and a process thereof forms a spacer including an L-shaped inner spacer and an outer spacer on the substrate beside the gate structure after the source/drain, the outer spacer is located on the L-shaped inner spacer, and the two ends of the L-shaped inner spacer protrude form the outer spacer. Therefore, the contact etch stop layer covering the spacer has a cross-sectional profile, enabling spacings between each of the gate structures to be reduced (which may be polysilicon gates or metal gates etc) and the spacings have an opening narrowing from top to bottom. Thus, cavities can be avoided from being generated, and a metal for forming contact plugs can be filled into the predetermined contact holes only without filling the cavities, so that contact plugs can be prevented from electrically contacting each other and short circuits will not occur.

Those skilled in the art will readily observe that numerous modifications and alterations of the device and method may be made while retaining the teachings of the invention. Accordingly, the above disclosure should be construed as limited only by the metes and bounds of the appended claims.

1. A MOS transistor, comprising:
a gate structure located on a substrate;
a spacer located on the substrate beside the gate structure, and the spacer comprises an L-shaped inner spacer and an outer spacer, wherein the outer spacer is located on the L-shaped inner spacer, and the two ends of the L-shaped inner spacer protrude from the outer spacer.

2. The MOS transistor according to claim 1, wherein the L-shaped inner spacer comprises an oxide spacer.

3. The MOS transistor according to claim 1, wherein the outer spacer comprises a nitride spacer.

4. The MOS transistor according to claim 1, wherein the outer spacer comprises a stress spacer.

5. The MOS transistor according to claim 1, further comprising:
a first spacer located between the gate structure and the spacer.

6. The MOS transistor according to claim 1, further comprising:
a contact etch stop layer covering the gate structure, the spacer and the substrate.

7. The MOS transistor according to claim 1, further comprising:
a source/drain located in the substrate beside the gate structure.

8. The MOS transistor according to claim 7, further comprising:
a metal silicide located on the source/drain.

9. The MOS transistor according to claim 1, further comprising:
a planarized interdielectric layer covering the spacer and the substrate, and at least a contact plug located in the interdielectric layer.

10. A MOS transistor process, comprising:
forming a gate structure on a substrate;
forming a spacer on the substrate beside the gate structure, wherein the spacer comprises an L-shaped inner spacer and an outer spacer and the L-shaped inner spacer and the outer spacer are formed by a same etching process, wherein the outer spacer is located on the L-shaped inner spacer, and the two ends of the L-shaped inner spacer protrude from the outer spacer.

11. The MOS transistor process according to claim 10, wherein the L-shaped inner spacer comprises an oxide spacer.

12. The MOS transistor process according to claim 10, wherein the outer spacer comprises a nitride spacer.

13. The MOS transistor process according to claim 10, wherein the outer spacer comprises a stress spacer.

14. The MOS transistor process according to claim 10, further comprising:
forming a main spacer on the substrate beside the gate structure after the gate structure is formed; and
forming a source/drain in the substrate beside the main spacer.

15. The MOS transistor process according to claim 14, wherein a method of forming the spacer comprises etching the main spacer.

16. The MOS transistor process according to claim 15, further comprising:
forming a metal silicide on the source/drain before the spacer is formed.

17. The MOS transistor process according to claim 15, further comprising:
forming a metal silicide on the source/drain after the spacer is formed.

18. The MOS transistor process according to claim 10, wherein a method of forming the spacer comprises:
covering a spacer material on the gate structure and the substrate; etching the spacer material to form the spacer.

19. The MOS transistor process according to claim 18, further comprising:
forming a main spacer on the substrate beside the gate structure before covering the spacer material;
forming a source/drain in the substrate beside the main spacer; and
removing the main spacer.

20. The MOS transistor process according to claim 10, wherein the spacer is formed by an etching process.

21. The MOS transistor process according to claim 20, wherein the etching process comprises a dry etching process or/and a wet etching process.

22. The MOS transistor process according to claim 20, wherein the etching process comprises sequentially performing two etching processes having different etching selectivities to the L-shaped inner spacer and the outer spacer.

23. The MOS transistor process according to claim 10, further comprising:
forming a first spacer on the substrate beside the gate structure after the gate structure is formed; and
forming a lightly doped source/drain in the substrate beside the first spacer.

24. The MOS transistor process according to claim 10, further comprising:
forming a contact etch stop layer to cover the gate structure, the spacer and the substrate after the spacer is formed.

25. The MOS transistor process according to claim 10, further comprising:
forming and planarizing an interdielectric layer to cover the spacer and the substrate after the spacer is formed; and
forming at least a contact hole in the planarized interdielectric layer.
